(19) United States
(12) Patent Application Publication
(10) Pub. No.: US 2024/0339315 A1
(43) Pub. Date: Oct. 10, 2024

(54) METHOD OF MANUFACTURING SILICON WAFERS

(71) Applicant: GLOBALWAFERS JAPAN CO., LTD., Kitakanbara-gun (JP)

(72) Inventors: Susumu MAEDA, Kitakanbara-gun (JP); Haruo SUDO, Kitakanbara-gun (JP); Hisashi MATSUMURA, Kitakanbara-gun (JP)

(73) Assignee: GLOBALWAFERS JAPAN CO., LTD., Kitakanbara-gun (JP)

(21) Appl. No.: 18/626,490

(22) Filed: Apr. 4, 2024

(30) Foreign Application Priority Data
Apr. 5, 2023 (JP) 2023-061727

(51) Int. Cl. H01L 21/02

(52) U.S. Cl. CPC H01L 21/0201

(57) ABSTRACT

To provide a method of manufacturing silicon wafers having a low oxygen concentration and being provided with the gettering capability of heavy metals even when the density of BMD is low. The method includes a step of placing wafers sliced from a silicon single crystal and having an oxygen concentration in the range of 1×10¹⁶ atoms/cm³ to 7×10¹⁷ atoms/cm³, in a chamber and a step of performing rapid thermal processing at a maximum temperature reached of not less than 1250° C. or not more than 1350° C. after introducing a mixed gas having an oxygen partial pressure in the range of 1% to 10% of oxygen and an inert gas.

### TECHNICAL FIELD

This invention relates to semiconductor wafers and methods for manufacturing silicon wafers, in particular a silicon wafer having a gettering capability and a method for manufacturing the silicon wafer.

### BACKGROUND ART

Metal oxide semiconductor field effect transistor (MOSFET) is one type of field effect transistor (FET) and has the most widely used among large-scale integrated circuits (LSI). For example, an insulated gate bipolar transistor (IGBT) used for the application of power control is one of the semiconductor devices that is a bipolar transistor in which MOSFET is incorporated in the main part.

The silicon wafers that are used for MOS power transistors such as IGBTs are conventionally required to have a low oxygen concentration in order to prevent lifetime degradation; high-resistivity silicon wafers with reduced oxygen concentration grown by the floating zone (FZ) method as described in JP-A-2021-118283 or epitaxial wafers that are laminated with low oxygen concentration epitaxial layers are used.

However, large-diameter single crystals, such as 300 mm or more, are difficult to grow using the FZ method, and the device yield using small-diameter wafers is insufficient. As a result, the FZ method is difficult to apply to green devices (energy-saving power devices), for which the demand is expected to grow.

Epitaxial wafers require a thick epitaxial layer for manufacturing vertical devices in MOS power transistors, and thereby the cost increases; therefore, epitaxial wafers are not suitable for green devices similar to the FZ-grown silicon wafers. The thickening of the epitaxial layers can lead to impair the perfectness of the epitaxial layers and increase the occurrence of current leakage which can lead to the failure of the MOS power transistors.

Thus, the application of silicon wafers using the MCZ method to power devices is focused, where the MCZ method is to control the crystal growth conditions by applying a magnetic field in the Czochralski method.

### CITATION LIST

### Patent Literature

PTL 1: JP-A-2021-118283

### SUMMARY OF INVENTION

### Technical Problem

For example, the silicon single crystal grown by the Czochralski method contains at least 5×10¹⁷ atoms/cm³ of oxygen due to the use of quartz glass crucibles in the conventional MCZ method. Silicon wafers sliced from the above single crystal contain oxygen precipitates (called BMD) formed during the single crystal growth, and the solid dissolved oxygen atoms newly form BMD in the manufacturing process of power devices; thus, the BMD can be the cause of occurrence of current leakage of the power devices.

Therefore, in order to use MCZ-grown silicon wafers for higher-grade power devices (high breakdown voltage and high switching speed), BMD, a cause of a malfunction, must be inhibited.

Meanwhile, it is also important to reduce heavy metal contamination to inhibit current leakage in the power devices.

For this reason, silicon wafers provided with a gettering capability while containing low oxygen concentration and inhibiting the formation of BMD have been required.

Under the above circumstances, the inventors have made an intensive study and found that when rapid thermal processing (RTP) is subjected to silicon wafers having a low oxygen concentration for a time scale of a few tens of seconds or less at a high temperature of 1250° C. or higher large defects in shape dimension such as BMD, which degrade the breakdown voltage, are not formed, and, meanwhile, micro-vacancy-oxygen-complex defects (hereinafter referred to as vacancy-oxygen-complex defects), which contribute to the gettering of heavy metals are formed, and arrived at the invention.

The object of this invention is to provide silicon wafers having low oxygen concentration and low density of BMD, but capability of gettering and a method of the silicon wafers.

### Solution to Problem

The silicon wafer has an oxygen concentration in the bulk region of 1×10¹⁶ atoms/cm³ to 7×10¹⁷ atoms/cm³ and a vacancy-based complex defect concentration of 1×10¹² atoms/cm³ or more within 100 μm in the depth direction from the wafer surface, and the BMD density is less than 1×10⁵ atoms/cm³ within 50 μm in the depth direction from the wafer surface.

In the region within 30 μm in the depth direction from the wafer surface, the wafers are preferred to have a concentration of vacancy-based complex defect of 1×10¹² atoms/cm³ or higher.

Thus, the silicon wafer has a low oxygen concentration in the bulk region of 1×10¹⁶ atoms/cm³ to 7×10¹⁷ atoms/cm³, and in the region from the wafer surface within 100 μm, the concentration of the vacancy-based complex defect gradually increases as it goes deeper from the surface, and desirably 1×10¹² atoms/cm³ or more within 30 μm in the depth direction from the wafer surface, and the BMD density is less than 1×10⁵ atoms/cm³ in the region within 50 μm in the depth direction from the wafer surface.

Accordingly, the wafer has a low oxygen concentration in the bulk region, and the gettering capability due to BMD is not high but due to the vacancy-based complex defects, the gettering capability of heavy metals is excellent.

The method of manufacturing silicon wafers according to the present invention for solving the above problem includes a step of placing wafers, sliced from a silicon single crystal and having an oxygen concentration in the range of 1×10¹⁶ atoms/cm³ to 7×10¹⁷ atoms/cm³, in a chamber and
a step of thermal treatment at the maximum temperature reached of not less than 1250° C. or not more than 1350° C. in the chamber into which an inert gas having an oxygen partial pressure in the range of 1% to 10% is introduced.

The method of manufacturing silicon wafers according to the present invention for solving the above problem includes a step of placing wafers, sliced from a silicon single crystal and having an oxygen concentration in the range of 1×10¹⁶ atoms/cm³ to 1×10¹⁷ atoms/cm³, in a chamber;
a step of introducing a mixed gas of oxygen and an inert gas having an oxygen partial pressure of more than 10% into the chamber; and
a step of heat treating at the maximum temperature reached within the region bounded by line segments given by a straight line connecting the two points (x, y)=(10%, 1250° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where the horizontal axis x is the logarithm of the oxygen partial pressure and the vertical axis y is the maximum temperature reached in the rapid heat treatment.

The method of manufacturing silicon wafers according to the present invention for solving the above problem includes a step of placing wafers, sliced from a silicon single crystal and having an oxygen concentration in the range of 1×10¹⁶ atoms/cm³ to 7×10¹⁷ atoms/cm³, in a chamber;
a step of introducing a mixed gas of oxygen and an inert gas having an oxygen partial pressure of more than 10% into the chamber, and
a step of heat treating at the maximum temperature reached within the region bounded by line segments given by a straight line connecting the two points (x, y)=(10%, 1250° C.) and (x, y)=(100%, 1300° C.), a straight line connecting the two points (x, y)=(100%, 1300° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where the horizontal axis x is the logarithm of the oxygen partial pressure and the vertical axis y is the maximum temperature reached in the rapid heat treatment.

By the above-described manufacturing method, a silicon wafer is obtainable, which has a low oxygen concentration in the bulk region of 1×10¹⁶ atoms/cm³ to 7×10¹⁷ atoms/cm³, the concentration of the vacancy-based complex defect of not less than 1×10¹² atoms/cm³ in the region within 100 μm in the depth direction from the wafer surface, and the BMD density of less than 1×10⁵ atoms/cm³ in the region within 50 μm in the depth direction from the wafer surface.

### Advantageous Effects of Invention

By this invention, silicon wafers having low oxygen concentration and low density of BMD but high gettering capability of heavy metals and a method of manufacturing the silicon wafers can be provided.

### BRIEF DESCRIPTION OF DRAWINGS

FIG. 1 is a cross-sectional view schematically illustrating the silicon wafers according to the present invention;

FIG. 2 is a cross-sectional view illustrating the outline of one example of a heat treatment apparatus for manufacturing the silicon wafers shown in FIG. 1;

FIG. 3 is a flowchart illustrating a first embodiment of the method of manufacturing the silicon wafers of the present invention;

FIG. 4 is a flowchart illustrating a second embodiment of the method of manufacturing the silicon wafers of the present invention;

FIG. 5 is a flowchart illustrating a third embodiment of the method of manufacturing the silicon wafers of the present invention;

FIG. 6 is a graph showing the results of Experiment 1 of the embodiment of the present invention;

FIG. 7 is a graph showing the other results of Experiment 1 of the embodiment of the present invention; and

FIG. 8 is a graph showing the results of Experiment 2 of the embodiment of the present invention.

### DESCRIPTION OF EMBODIMENTS

A preferable embodiment of the present invention will be described based on the drawings.

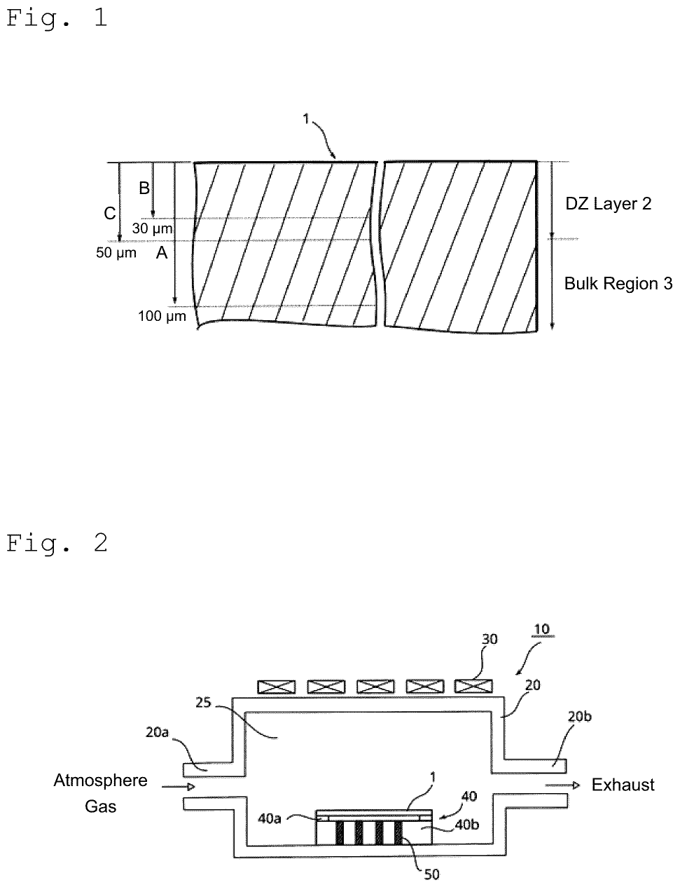

FIG. 1 is a cross-sectional view schematically illustrating the silicon wafers according to the present invention. As shown in FIG. 1, a DZ layer 2, a defect-free region (a denuded zone), is formed on the surface side of the silicon wafer 1. The lower region below the DZ layer 2 is a bulk region 3, and the bulk region 3 is formed 30 μm down from the wafer surface, more preferably 50 μm down.

The silicon wafer 1 has a low oxygen concentration, with the oxygen concentration in the bulk region 3 being between 1×10¹⁶ atoms/cm³ and 7×10¹⁷ atoms/cm³. In the depth region A within 100 μm from the wafer surface, the concentration of vacancy-based complex defects (micro vacancy-oxygen complex defects) gradually increases with depth from the surface, reaching 1×10¹² atoms/cm³ or more in region B within 30 μm from the wafer surface. Thus, by having vacancy complex defects with a concentration of 1×10¹² atoms/cm³ or higher on the surface side of the wafer, the gettering ability of heavy metals such as Ni and Cu can be fully provided.

Furthermore, the silicon wafer 1 has a BMD density of less than 1×10⁵ atoms/cm³ in the area C within 50 μm of the surface. This low BMD density reduces the BMD gettering capability, but suppresses the generation of leakage current, making it suitable for applications in power devices and imaging devices such as CMOS image sensors.

FIG. 2 is a cross-sectional view of an example of a heat treatment apparatus (RTP apparatus) used to manufacture the silicon wafers shown in FIG. 1. As shown in FIG. 2, the heat treatment apparatus 10 includes a chamber (reaction tube) 20 provided with an atmosphere gas inlet 20a and an atmosphere gas outlet 20b, a plurality of lamps 30 spaced apart at the top of the chamber 20, and a wafer support 40 for supporting a silicon wafer 1 in a reaction space 25 in the chamber 20. Although not shown in the drawing, a rotating means for rotating the silicon wafer 1 at a predetermined speed about its central axis is provided.

The wafer support 40 has an annular susceptor 40a that supports the outer circumference of the silicon wafer 1 and a stage 40b that supports the susceptor 40a. The chamber 20 is composed of, for example, quartz. The lamp 30 is composed of, for example, a halogen lamp. The susceptor 40a is made of, for example, silicon carbide (SiC). The stage 40b is composed of, for example, quartz.

When heat treatment is performed on a silicon wafer 1 with a heat treatment apparatus 10 shown in FIG. 2, the silicon wafer 1 is introduced into a reaction space 25 through a substrate introduction port (not shown) of the chamber 20 and mounted on a susceptor 40a of the wafer support 40. Then, the heat treatment is performed by introducing the atmosphere gas described below from the atmosphere gas inlet 20a and irradiating lamp light by the lamp 30 on the wafer surface while rotating the silicon wafer 1 by a rotating means not shown in the figure.

The average temperature at multiple points (e.g., 9 points) in the wafer radial direction of the lower surface of the silicon wafer 1 is measured by the multiple radiation thermometer 50 buried in the stage 40b of the wafer support 40. The temperature control in the reaction space 25 of the heat treatment apparatus 10 is performed by controlling the multiple lamps 30 based on the measured temperature (individual ON-OFF control of each lamp or light intensity control of the emitted light).

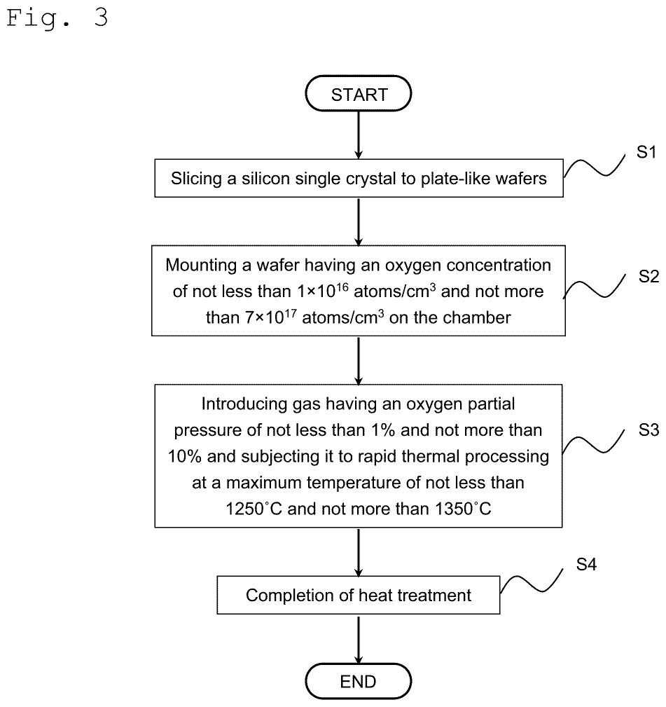

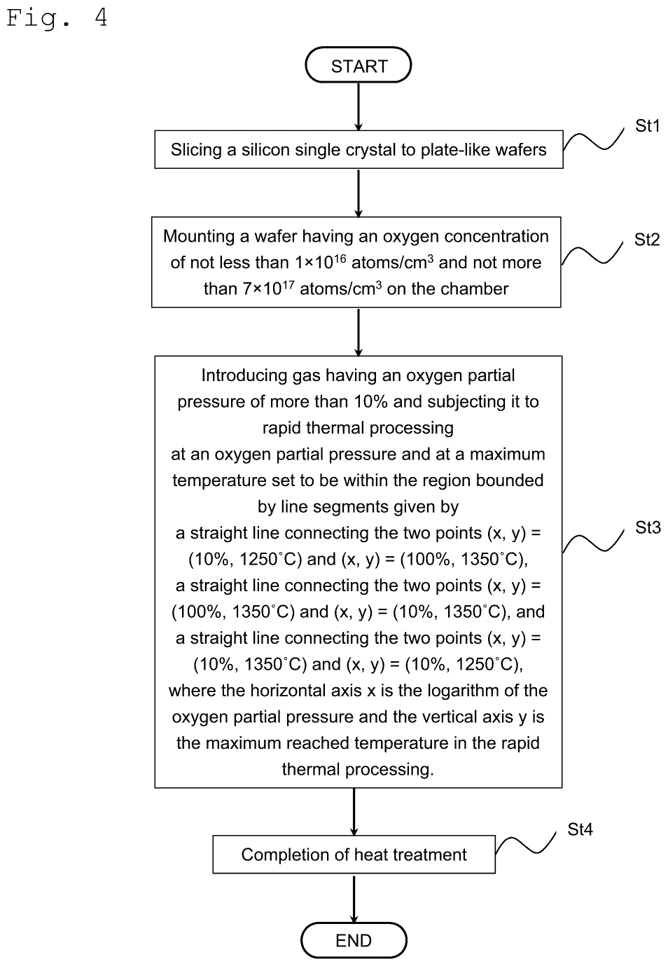

A first embodiment of the method of manufacturing silicon wafers of the invention will be described based on the flow chart of FIG. 3. In the method of manufacturing silicon wafers of the invention, the silicon wafers sliced from a single crystal silicon ingot grown by the Czochralski method (CZ method), for example, are subjected to heat treatment under the predetermined manufacturing condition.

Single crystal silicon ingots by the Czochralski method are grown with a well-known procedure.

That is, polycrystalline silicon filled in a quartz crucible is heated to form a silicon melt, a seed crystal is brought into contact with the silicon melt from above the liquid surface, and the seed crystal is pulled up while rotating the seed crystal and the crucible to produce a silicon single crystal ingot of the desired diameter. The silicon single crystal ingot to be pulled up should be grown by suppressing the convection of the silicon melt by applying a magnetic field using the MCZ method and by slowing down the single crystal rotation speed and the crucible rotation speed to keep the oxygen concentration between 1×10¹⁶ atoms/cm³ and 7×10¹⁷ atoms/cm³. However, silicon monocrystals can be grown not only by the MCZ method but also by the CZ method or the FZ method, for example, without applying a magnetic field.

The grown single-crystal silicon ingot is processed into silicon wafers by the well-known method (see step S1 in FIG. 3).

In other words, silicon wafers are formed by subjecting the single crystal silicon ingot to processing such as chamfering, lapping, etching, and polishing after being sliced plate-like by an internal peripheral blade slicing machine or a wire saw. Thus, silicon wafers having an oxygen concentration between 1×10¹⁶ atoms/cm³ and 7×10¹⁷ atoms/cm³ are obtained.

The processing steps described herein are exemplary and the invention is not limited to only the above processing steps.

Next, the obtained silicon wafers are subjected to heat treatment under the predetermined conditions. Specifically, the silicon wafers are accommodated in the chamber 20 being maintained at a predetermined initial temperature in the heat treatment apparatus 10 shown in FIG. 2 (step S2 in FIG. 3).

After accommodating the silicon wafers, a mixed gas of oxygen (O2) and an inert gas having an oxygen partial pressure set between 1% and 10% is introduced into the chamber 20 from the atmosphere gas inlet 20a at a predetermined flow rate. Argon (Ar) gas and nitrogen gas can be selected as the inert gas.

Further, the temperature in the chamber 20 is heated by a lamp at a temperature rise rate (30° C./s or more and 100° C./s or less), and the silicon wafers are subjected to rapid thermal processing (RTP) at the maximum reached temperature of 1250° C. or more and 1350° C. or less for a predetermined time (for example, 10 s or more and 50 s or less) (step S3 in FIG. 3).

To control the oxygen partial pressure in the heat treatment space to be constant, the gas in the chamber is exhausted from the atmosphere gas outlet 20b at a predetermined flow rate.

After completing the heat treatment at a high temperature, the temperature in the chamber is lowered at a predetermined temperature drop rate (10° C./s or more and 150° C./s or less) to a predetermined temperature, and the heat treatment is completed (step S4 in FIG. 3).

BMD which is likely to be a source of current leakage in a device is hardly formed in the surface layer of the silicon wafer to be an active layer of the device in the silicon wafers 1 due to the rapid thermal processing like this. The vacancies introduced by the heat treatment react with oxygen at an extremely low concentration and form vacancy-oxygen complex defects (vacancy-based complex defects), which is a gettering source of heavy metals such as iron Fe, nickel Ni, copper Cu, or others.

Specifically, in the silicon wafer 1, a region with a concentration of vacancy complex defects exceeding 1×10¹² atoms/cm³ is formed at a depth of 100 μm or less from the wafer surface. In the depth region within 100 μm from the wafer surface, the concentration of vacancy complex defects gradually increases with depth from the surface and is greater than 1×10¹² atoms/cm³ in the region within 30 μm from the wafer surface.

In addition, silicon wafer 1 is formed with a low BMD density of less than 1×10⁵ atoms/cm³ in the region within 50 μm from the surface, and the generation of current leakage caused by BMD can be suppressed.

The silicon wafers 1 according to the present invention are obtained, after the heat treatment of the silicon wafers 1 which are taken out of the chamber 20 and from which an oxide film formed on the surface of the silicon wafer 1 by the heat treatment is removed by an HF cleaning, for example.

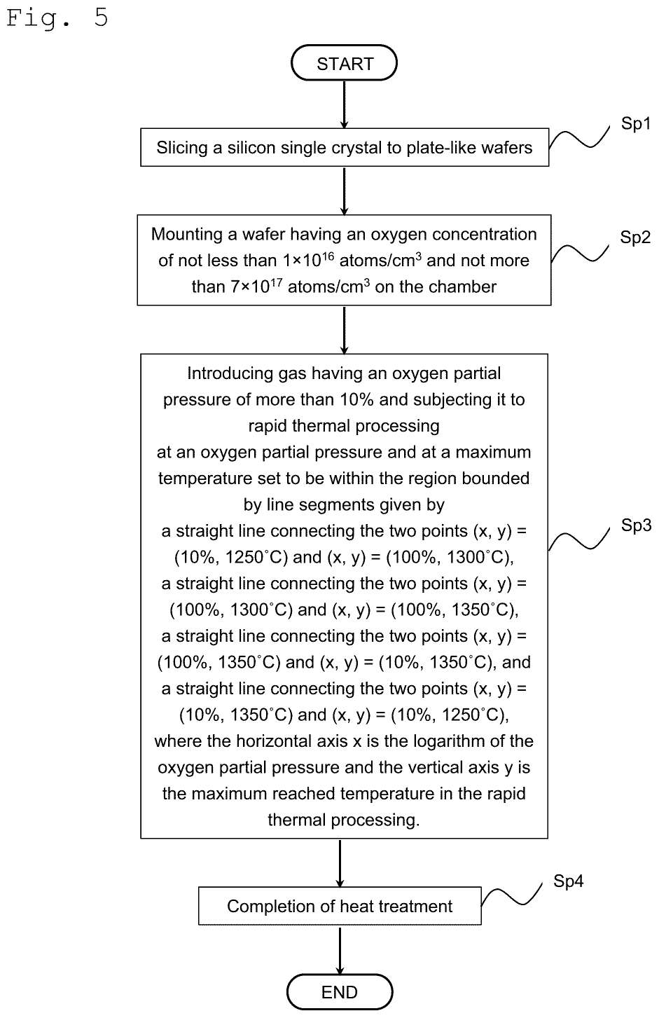

A second embodiment of the method of manufacturing silicon wafers according to the present invention is then described along the flow chart in FIG. 4.

In the second embodiment, as in the first embodiment, heat treatment is performed on silicon wafers sliced from silicon single crystal ingots grown, for example, by the Czochralski method (CZ method), according to predetermined manufacturing conditions.

Single crystal silicon ingots by the Czochralski method are grown with a well-known procedure.

That is, polycrystalline silicon filled in a quartz crucible is heated to form a silicon melt, a seed crystal is brought into contact with the silicon melt from above the liquid surface, and the seed crystal is pulled up while rotating the seed crystal and the crucible to produce a silicon single crystal ingot of the desired diameter. The silicon single crystal ingot to be pulled up should be grown by suppressing the convection of the silicon melt by applying a magnetic field using the MCZ method and by slowing down the single crystal rotation speed and the crucible rotation speed to keep the oxygen concentration between 1×10¹⁶ atoms/cm³ and 7×10¹⁷ atoms/cm³. However, silicon monocrystals can be grown not only by the MCZ method but also by the CZ method or the FZ method, for example, without applying a magnetic field.

The grown single-crystal silicon ingot is processed into silicon wafers by the well-known method (Step St1 in FIG. 4).

In other words, silicon wafers are formed by subjecting the single crystal silicon ingot to processing such as chamfering, lapping, etching, and polishing after being sliced plate-like by an internal peripheral blade slicing machine or a wire saw. Thus, silicon wafers having an oxygen concentration between 1×10¹⁶ atoms/cm³ and 7×10¹⁷ atoms/cm³ are obtained.

The processing steps described herein are exemplary and the invention is not limited to only the above processing steps.

Next, the obtained silicon wafers are subjected to heat treatment under the predetermined conditions. Specifically, the silicon wafers are accommodated in the chamber 20 being maintained at a predetermined initial temperature in the heat treatment apparatus 10 shown in FIG. 2 (Step St2 in FIG. 4).

After accommodating the silicon wafers, a mixed gas of oxygen (O₂) and an inert gas having an oxygen partial pressure set to more than 10% (70%, for example) is introduced into the chamber 20 from the atmosphere gas inlet 20a at a predetermined flow rate. Argon (Ar) gas and nitrogen gas can be selected as the inert gases.

Then, the inside of the chamber 20 is heated with the lamp 30 at a temperature rise rate (30° C./s or more and 100° C./s or less), and rapid thermal processing (RTP) is performed for a predetermined time duration (for example, 10 s or more and 50 s or less) (Step St3 in FIG. 4).

The oxygen partial pressure and the maximum reached temperature are set to be within the region bounded by line segments given by a straight line connecting the two points (x, y)=(10%, 1250° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where the horizontal axis x is the logarithm of the oxygen partial pressure and the vertical axis y is the maximum reached temperature in the rapid thermal processing.

To control the oxygen partial pressure in the heat treatment space to be constant, the gas in the chamber is exhausted from the atmosphere gas outlet 20b at a predetermined flow rate.

After completing the heat treatment at a high temperature, the temperature in the chamber is lowered at a predetermined temperature drop rate (10° C./s or more and 150° C./s or less) to a predetermined temperature, and the heat treatment is completed (Step St4 in FIG. 4).

BMD which is likely to be a source of current leakage in a device is hardly formed in the surface layer of the silicon wafer to be an active layer of the device in the silicon wafers 1 due to the rapid thermal processing like this. The vacancies introduced by the heat treatment react with oxygen at an extremely low concentration and form vacancy-oxygen complex defects (vacancy-based complex defects), which is a gettering source of heavy metals such as iron Fe, nickel Ni, copper Cu, or others.

Specifically, in the silicon wafer 1, regions with a concentration of vacancy complex defects exceeding 1×10¹² atoms/cm³ are formed at a depth of 100 μm or less from the wafer surface. In the depth region within 100 μm from the wafer surface, the concentration of vacancy complex defects gradually increases with depth from the surface and is greater than 1×10¹² atoms/cm³ in the region within 30 μm from the wafer surface.

In addition, silicon wafer 1 is formed with a low BMD density of less than 1×10⁵ atoms/cm³ in the region within 50 μm from the surface, and the generation of current leakage caused by BMD can be suppressed.

The silicon wafers 1 according to the present invention are obtained, after the heat treatment of the silicon wafers 1 which are taken out of the chamber 20 and from which an oxide film formed on the surface of the silicon wafer 1 by the heat treatment is removed by an HF cleaning.

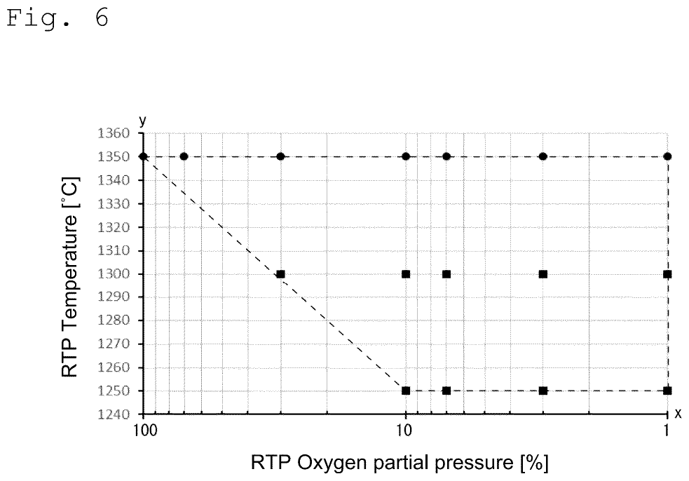

A third embodiment of the method of manufacturing silicon wafers according to the present invention is then described along the flow chart in FIG. 5.

In the third embodiment, similar to the first and second embodiments, heat treatment is performed on silicon wafers sliced from silicon single crystal ingots grown, for example, by the Czochralski method (CZ method), according to predetermined manufacturing conditions.

Single crystal silicon ingots by the Czochralski method are grown with a well-known procedure.

That is, polycrystalline silicon filled in a quartz crucible is heated to form a silicon melt, a seed crystal is brought into contact with the silicon melt from above the liquid surface, and the seed crystal is pulled up while rotating the seed crystal and the crucible to produce a silicon single crystal ingot of the desired diameter. The silicon single crystal ingot to be pulled up should be grown by suppressing the convection of the silicon melt by applying a magnetic field using the MCZ method and by slowing down the single crystal rotation speed and the crucible rotation speed to keep the oxygen concentration between 1×10¹⁷ atoms/cm³ and 7×10¹⁷ atoms/cm³. However, silicon monocrystals can be grown not only by the MCZ method but also by the CZ method or the FZ method, for example, without applying a magnetic field.

The grown single-crystal silicon ingot is processed into silicon wafers by the well-known method (Step Sp1 in FIG. 5).

In other words, silicon wafers are formed by subjecting the single crystal silicon ingot to processing such as chamfering, lapping, etching, and polishing after being sliced plate-like by an internal peripheral blade slicing machine or a wire saw. Thus, silicon wafers having an oxygen concentration between 1×10¹⁷ atoms/cm³ and 7×10¹⁷ atoms/cm³ are obtained.

The processing steps described herein are exemplary and the invention is not limited to only the above processing steps.

Next, the obtained silicon wafers are subjected to heat treatment under the predetermined conditions. Specifically, the silicon wafers are accommodated in the chamber 20 being maintained at a predetermined initial temperature in the heat treatment apparatus 10 shown in FIG. 2 (step Sp2 in FIG. 5).

After accommodating the silicon wafers, a mixed gas of oxygen (O₂) and an inert gas having an oxygen partial pressure set to more than 10% (70%, for example) is introduced into the chamber 20 from the atmosphere gas inlet 20a at a predetermined flow rate. Argon (Ar) gas and nitrogen gas can be selected as the inert gas.

Then, the inside of the chamber 20 is heated with the lamp 30 at a temperature rise rate (30° C./s or more and 100° C./s or less), and rapid thermal processing (RTP) is performed for a predetermined time duration (for example, 10 s or more and 50 s or less) (step Sp3 in FIG. 5).

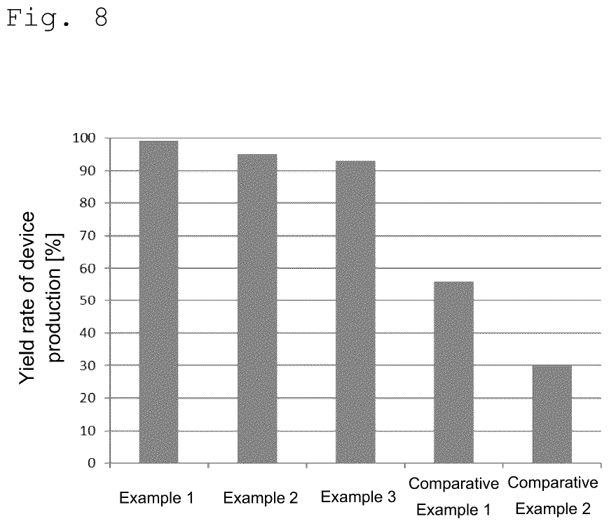

The oxygen partial pressure and the maximum reached temperature are set to be within the region bounded by line segments given by a straight line connecting the two points (x, y)=(10%, 1250° C.) and (x, y)=(100%, 1300° C.), a straight line connecting the two points (x, y)=(100%, 1300° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where, as shown in FIG. 7, the horizontal axis x is the logarithm of the oxygen partial pressure and the vertical axis y is the maximum reached temperature in the rapid thermal processing.

To control the oxygen partial pressure in the heat treatment space to be constant, the gas in the chamber is exhausted from the atmosphere gas outlet 20b at a predetermined flow rate.

After completing the heat treatment at a high temperature, the temperature in the chamber is lowered at a predetermined temperature drop rate (10° C./s or more and 150° C./s or less) to a predetermined temperature, and the heat treatment is completed (step Sp4 in FIG. 5).

BMD which is likely to be a source of current leakage in a device is hardly formed in the surface layer of the silicon wafer to be an active layer of the device in the silicon wafers 1 due to the rapid thermal processing like this. The vacancies introduced by the heat treatment react with oxygen at an extremely low concentration and form vacancy-oxygen complex defects (vacancy-based complex defects), which is a gettering source of heavy metals such as iron Fe, nickel Ni, copper Cu, or others.

Specifically, in the silicon wafer 1, regions with a concentration of vacancy complex defects exceeding 1×10¹² atoms/cm³ are formed at a depth of 100 μm or less from the wafer surface. In the depth region within 100 μm from the wafer surface, the concentration of vacancy complex defects gradually increases with depth from the surface and is greater than 1×10¹² atoms/cm³ in the region within 30 μm from the wafer surface.

In addition, silicon wafer 1 is formed with a low BMD density of less than 1×10⁵ atoms/cm³ in the region within 50 μm from the surface, and the generation of current leakage caused by BMD can be suppressed.

The silicon wafers 1 according to the present invention are obtained, after the heat treatment of the silicon wafers 1 which are taken out of the chamber 20 and from which an oxide film formed on the surface of the silicon wafer 1 by the heat treatment is removed by an HF cleaning.

Thus, according to embodiments of the present invention, the silicon wafer 1 has a low oxygen concentration in the bulk region of 1×10¹⁶ atoms/cm³ to 7×10¹⁷ atoms/cm³, and in the region from the wafer surface within 100 μm, the concentration of the vacancy-based complex defect gradually increases as it goes deeper from the surface, and 1×10¹² atoms/cm³ or more within 30 μm in the depth direction from the wafer surface.

Accordingly, the wafer has a low oxygen concentration in the bulk region and the gettering capability due to BMD is not high but due to the vacancy-based complex defects, the gettering capability of heavy metals is excellent.

In addition, silicon wafer 1 is formed with a low BMD density of less than 1×10⁵ atoms/cm³ in the region within 50 μm from the surface, and the generation of current leakage caused by BMD can be suppressed.

In the above embodiments, silicon wafers are prepared from silicon single crystals grown by the CZ method, but not limited to the above, silicon wafers may be prepared from silicon single crystals grown by the FZ method.

### EXAMPLES

The silicon wafers and the manufacturing method of silicon wafers according to the present invention will be further described based on examples. In the examples, the following experiments are performed based on the embodiments described above.

### Experiment 1

### Conditions 1 to 21

Under conditions of 1 to 21, to grow silicon single crystals with low oxygen concentration, silicon single crystals with an oxygen concentration of 1×10¹⁶ atoms/cm³ were pulled up by controlling the rotation speed of a quartz glass crucible at low speed while applying a magnetic field using the MCZ method.

The silicon single crystals were then sliced into silicon wafers with a diameter of 300 mm, thickness of 775 μm, and an oxygen concentration of 1×10¹⁶ atoms/cm³. The wafers were placed in the chamber 20 shown in FIG. 2, and were subjected to RTP (heating rate of 75° C./s, with a holding time at the maximum temperature reached of 20 seconds, and cooled at a temperature drop rate of 120° C./s), then the BMD density and the concentration of vacancy-based complex defects, formed on the silicon wafer were measured.

The conditions 1 through 21 are each of the combination of three maximum temperatures reached of 1350° C., 1300° C., and 1250° C. and seven partial pressures of 100%, 70%, 30%, 10%, 7%, 3%, and 1%, totally 21 conditions.

After the heat treatment, an oxide layer formed on the surface of the silicon wafer is removed by HF cleaning. Then, to check the oxygen vacancies by revealing, silicon wafers are housed in the chamber and heat-treated for three hours at 780° C., then, in succession, for 8 hours at 1000° C. The density of BMD and concentration of vacancy-based complex defects are measured with IR tomography (MO-441 manufactured by System Seiko Co., Ltd.).

The concentration of vacancy-based complex defects should be 1×10¹² atoms/cm³ or more in a region within 100 μm in the depth direction from the wafer surface, more preferably within 30 μm, because the gettering capability for Ni and Cu is sufficiently high. The BMD density should be 1×10⁵ atoms/cm³ or less in the region within 50 μm in the depth direction from the surface because the generation of current leakage can be suppressed.

Table 1 shows the results of Experiment 1 under the conditions 1 through 21. In Table 1, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 1

| Oxygen | | | | | | | | |
|---|---|---|---|---|---|---|---|---|
| Concentration of Wafers | | Oxygen Partial Pressure (%) | | | | | | |
| 1 × 10¹⁶ atoms/cm³ | | 100 | 70 | 30 | 10 | 7 | 3 | 1 |
| Maximum | 1350 | Good | Good | Good | Good | Good | Good | Good |
| Temperature | | | | | | | | |
| Reached | 1300 | Fair | Fair | Good | Good | Good | Good | Good |
| (° C.) | 1250 | Fair | Fair | Fair | Good | Good | Good | Good |

As shown in Table 1, when the oxygen concentration of the silicon wafer is 1×10¹⁶ atoms/cm³ excellent results were obtained regardless of the oxygen partial pressure at the maximum temperature reached of 1350° C.

When the maximum temperature reached is 1300° C., the concentration of the vacancy-based complex defects within the wafer surface of less than 1×10¹² atoms/cm³ at the oxygen partial pressure of 70% or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface of less than 1×10¹² atoms/cm³ and the density of BMD within the wafer surface of 1×10⁵ atoms/cm³ or more.

### Conditions 22 to 42

Under conditions of 22 to 42, silicon single crystals with an oxygen concentration of 1×10¹⁶ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 5×10¹⁶ atoms/cm³ were used. Other conditions are similar to the conditions 1 through 21.

Table 2 shows the results of Experiment 1 under the conditions 22 through 42. In Table 2, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 2

| Oxygen | | | | | | | | |
|---|---|---|---|---|---|---|---|---|
| Concentration of Wafers | | Oxygen Partial Pressure (%) | | | | | | |
| 5 × 10¹⁶ atoms/cm³ | | 100 | 70 | 30 | 10 | 7 | 3 | 1 |
| Maximum | 1350 | Good | Good | Good | Good | Good | Good | Good |
| Temperature | | | | | | | | |
| Reached | 1300 | Fair | Fair | Good | Good | Good | Good | Good |
| (° C.) | 1250 | Fair | Fair | Fair | Good | Good | Good | Good |

As shown in Table 2, when the oxygen concentration of the silicon wafer is 5×10¹⁶ atoms/cm³, excellent results were obtained at the maximum temperature reached of 1350° C., regardless of the oxygen partial pressure. That is, at this temperature, the concentration of the vacancy-based complex defects within the wafer surface of 1×10¹² atoms/cm³ or more, though the density of BMD within the wafer surface of less than 1×10⁵ atoms/cm³.

When the maximum temperature reached is 1300° C., the concentration of the vacancy-based complex defects within the wafer surface of less than 1×10¹² atoms/cm³ at the oxygen partial pressure of 70% or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface of less than 1×10¹² atoms/cm³ and the density of BMD within the wafer surface of 1×10⁵ atoms/cm³ or more.

### Condition 43 to 63

Under conditions of 43 to 63, silicon single crystals with an oxygen concentration of 9×10¹⁶ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 9×10¹⁶ atoms/cm³ were used. Other conditions are similar to the conditions 1 through 21.

Table 3 shows the results of Experiment 1 under the conditions 43 through 63. In Table 3, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 3

| Oxygen | | | | | | | | |
|---|---|---|---|---|---|---|---|---|
| Concentration of Wafers | | Oxygen Partial Pressure (%) | | | | | | |
| 9 × 10¹⁶ atoms/cm³ | | 100 | 70 | 30 | 10 | 7 | 3 | 1 |
| Maximum | 1350 | Good | Good | Good | Good | Good | Good | Good |
| Temperature | | | | | | | | |
| Reached | 1300 | Fair | Fair | Good | Good | Good | Good | Good |
| (° C.) | 1250 | Fair | Fair | Fair | Good | Good | Good | Good |

As shown in Table 3, when the oxygen concentration of the silicon wafer is 9×10¹⁶ atoms/cm³, excellent results were obtained at the maximum temperature reached of 1350° C. regardless of the oxygen partial pressure. That is, at this temperature, the concentration of the vacancy-based complex defects within the wafer surface of 1×10¹² atoms/cm³ or more, though the density of BMD within the wafer surface of less than 1×10⁵ atoms/cm³.

When the maximum temperature reached is 1300° C., the concentration of the vacancy-based complex defects within the wafer surface of less than 1×10¹² atoms/cm³ at the oxygen partial pressure of 70% or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface is less than 1×10¹² atoms/cm³ and the density of BMD within the wafer surface is 1×10⁵ atoms/cm³ or more.

### Condition 64 to 84

Under conditions of 64 to 84, silicon single crystals with an oxygen concentration of 1×10¹⁷ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 1×10¹⁷ atoms/cm³ were used. Other conditions are similar to the conditions 1 through 21.

Table 4 shows the results of Experiment 1 under the conditions 64 through 84. In Table 4, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 4

| Oxygen | | | | | | | | |
|---|---|---|---|---|---|---|---|---|
| Concentration of Wafers | | Oxygen Partial Pressure (%) | | | | | | |
| 1 × 10¹⁷ atoms/cm³ | | 100 | 70 | 30 | 10 | 7 | 3 | 1 |
| Maximum | 1350 | Good | Good | Good | Good | Good | Good | Good |
| Temperature | | | | | | | | |
| Reached | 1300 | Good | Good | Good | Good | Good | Good | Good |
| (° C.) | 1250 | Fair | Fair | Fair | Good | Good | Good | Good |

As shown in Table 4, when the oxygen concentration of the silicon wafer is 1×10¹⁷ atoms/cm³ excellent results were obtained at the maximum temperature reached of 1350° C. and 1300° C. regardless of the oxygen partial pressure. That is, at this temperature, the concentration of the vacancy-based complex defects within the wafer surface of 1×10¹² atoms/cm³ or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface of less than 1×10¹² atoms/cm³ and the density of BMD within the wafer surface of 1×10⁵ atoms/cm³ or more.

### Condition 85 to 10⁵

Under conditions of 85 to 10⁵, silicon single crystals with an oxygen concentration of 5×10¹⁷ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 5×10¹⁷ atoms/cm³ were used. Other conditions are similar to the conditions 1 through 21.

Table 5 shows the results of Experiment 1 under the conditions 85 through 10⁵. In Table 5, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 5

| Oxygen | | | | | | | | |
|---|---|---|---|---|---|---|---|---|
| Concentration of Wafers | | Oxygen Partial Pressure (%) | | | | | | |
| 5 × 10¹⁷ atoms/cm³ | | 100 | 70 | 30 | 10 | 7 | 3 | 1 |
| Maximum | 1350 | Good | Good | Good | Good | Good | Good | Good |
| Temperature | | | | | | | | |
| Reached | 1300 | Good | Good | Good | Good | Good | Good | Good |
| (° C.) | 1250 | Fair | Fair | Fair | Good | Good | Good | Good |

As shown in Table 5, when the oxygen concentration of the silicon wafer is 5×10¹⁷ atoms/cm³, excellent results were obtained at the maximum temperature reached of 1350° C. and 1300° C. regardless of the oxygen partial pressure. That is, at this temperature, the concentration of the vacancy-based complex defects within the wafer surface of 1×10¹² atoms/cm³ or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface of less than 1×10¹² atoms/cm³ and the density of BMD within the wafer surface of 1×10⁵ atoms/cm³ or more.

### Condition 10⁵ to 126

Under conditions of 105 to 126, silicon single crystals with an oxygen concentration of 7×10¹⁷ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 7×10¹⁷ atoms/cm³ were used. Other conditions are similar to the conditions 1 through 21.

Table 6 shows the results of Experiment 1 under the conditions 105 through 126. In Table 6, the condition that gives the concentration of the vacancy-based complex defects within the wafer surface of 1×10¹² atoms/cm³ or more and the density of BMD within the wafer surface of less than 1×10⁵ atoms/cm³ for the combination of time duration and temperature of the heat treatment is designated as “Good”.

The condition that gives the concentration of the vacancy-based complex defects within the wafer surface of less than 1×10¹² atoms/cm³ and the density of BMD within the wafer surface of less than 1×10⁵ atoms/cm³ for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 6

| Oxygen | | | | | | | | |
|---|---|---|---|---|---|---|---|---|
| Concentration of Wafers | | Oxygen Partial Pressure (%) | | | | | | |
| 7 × 10¹⁷ atoms/cm³ | | 100 | 70 | 30 | 10 | 7 | 3 | 1 |
| Maximum | 1350 | Good | Good | Good | Good | Good | Good | Good |
| Temperature | 1300 | Good | Good | Good | Good | Good | Good | Good |
| Reached | | | | | | | | |
| (° C.) | 1250 | Fair | Fair | Fair | Good | Good | Good | Good |

As shown in Table 6, when the oxygen concentration of the silicon wafer is 7×10¹⁷ atoms/cm³, excellent results were obtained at the maximum temperature reached of 1350° C. and 1300° C. regardless of the oxygen partial pressure. That is, at this temperature, the concentration of the vacancy-based complex defects within the wafer surface of 1×10¹² atoms/cm³ or more, though the density of BMD within the wafer surface of less than 1×10⁵ atoms/cm³.

When the maximum temperature reached is 1250° C., the concentration of the vacancy-based complex defects within the wafer surface of less than 1×10¹² atoms/cm³ at the oxygen partial pressure of 30% or more, though the density of BMD within the wafer surface of less than 1×10⁵ atoms/cm³.

There was no condition under which the concentration of the vacancy-based complex defects within the wafer surface of less than 1×10¹² atoms/cm³ and the density of BMD within the wafer surface of 1×10⁵ atoms/cm³ or more.

### Conditions 127 to 147

Under conditions of 127 to 147, silicon single crystals with an oxygen concentration of 8×10¹⁷ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 8×10¹⁷ atoms/cm³ were used. Other conditions are similar to the conditions 1 through 21.

Table 7 shows the results of Experiment 1 under the conditions 127 through 147. In Table 7, the condition that gives the concentration of the vacancy-based complex defects within the wafer surface of 1×10¹² atoms/cm³ or more and the density of BMD within the wafer surface of 1×10⁵ atoms/cm³ or more for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 7

| Oxygen | | | | | | | | |
|---|---|---|---|---|---|---|---|---|
| Concentration of Wafers | | Oxygen Partial Pressure (%) | | | | | | |
| 8 × 10¹⁷ atoms/cm³ | | 100 | 70 | 30 | 10 | 7 | 3 | 1 |
| Maximum | 1350 | Fair | Fair | Fair | Fair | Fair | Fair | Fair |
| Temperature | | | | | | | | |
| Reached | 1300 | Fair | Fair | Fair | Fair | Fair | Fair | Fair |
| (° C.) | 1250 | Poor | Poor | Fair | Fair | Fair | Fair | Fair |

As shown in Table 7, when the oxygen concentration of the silicon wafer is 8×10¹⁷ atoms/cm³, at the maximum temperature reached of 1350° C. and 1300° C., regardless of the oxygen partial pressure, the concentration of the vacancy-based complex defects within the wafer surface is 1×10¹² atoms/cm³ or more and the density of BMD within the wafer surface is less than 1×10⁵ atoms/cm³.

When the maximum temperature reached is 1250° C., the concentration of the vacancy-based complex defects within the wafer surface of 1×10¹² atoms/cm³ or more at the oxygen partial pressure of 30% or less, and the density of BMD within the wafer surface is 1×10⁵ atoms/cm³ or more.

The concentration of the vacancy-based complex defects within the wafer surface of less than 1×10¹² atoms/cm³ at the oxygen partial pressure of 70% or less, and the density of BMD within the wafer surface is 1×10⁵ atoms/cm³ or more.

### Condition 147 to 168

Under conditions of 147 to 168, silicon single crystals with an oxygen concentration of 1×10¹⁸ atoms/cm³ were pulled up by controlling the rotation speed of a quartz glass crucible at low speed while applying a magnetic field using the MCZ method. The silicon single crystals were then sliced, and the obtained silicon wafers with an oxygen concentration of 1×10¹⁸ atoms/cm³ were used. Other conditions are similar to the conditions 1 through 21.

Table 8 shows the results of Experiment 1 under the conditions 148 through 168. In Table 8, the condition that gives the concentration of the vacancy-based complex defects within the wafer surface of 1×10¹² atoms/cm³ or more and the density of BMD within the wafer surface of 1×10⁵ atoms/cm³ or more for the combination of time duration and temperature of the heat treatment is designated as “Fair”.

The condition that gives the concentration of the vacancy-based complex defects within the wafer surface of less than 1×10¹² atoms/cm³ and the density of BMD within the wafer surface of 1×10⁵ atoms/cm³ or more for the combination of time duration and temperature of the heat treatment is designated as “Poor”.

TABLE 8

| Oxygen | | | | | | | | |
|---|---|---|---|---|---|---|---|---|
| Concentration of Wafers | | Oxygen Partial Pressure (%) | | | | | | |
| 1 × 10¹⁸ atoms/cm³ | | 100 | 70 | 30 | 10 | 7 | 3 | 1 |
| Maximum | 1350 | Fair | Fair | Fair | Fair | Fair | Fair | Fair |
| Temperature | | | | | | | | |
| Reached | 1300 | Fair | Fair | Fair | Fair | Fair | Fair | Fair |
| (° C.) | 1250 | Poor | Poor | Fair | Fair | Fair | Fair | Fair |

As shown in Table 8, when the oxygen concentration of the silicon wafer is 1×10¹⁸ atoms/cm³, at the maximum temperature reached of 1350° C. and 1300° C., regardless of the oxygen partial pressure, the concentration of the vacancy-based complex defects within the wafer surface is 1×10¹² atoms/cm³ or more, and the density of BMD within the wafer surface is 1×10⁵ atoms/cm³ or more.

When the maximum temperature reached is 1250° C., at the oxygen partial pressure of 30% or less, the concentration of the concentration of the vacancy-based complex defects within the wafer surface of 1×10¹² atoms/cm³ or more, and the density of BMD within the wafer surface is 1×10⁵ atoms/cm³ or more.

The concentration of the vacancy-based complex defects within the wafer surface is less than 1×10¹² atoms/cm³ at the oxygen partial pressure of 70% or less, and the density of BMD within the wafer surface is 1×10⁵ atoms/cm³ or more.

The concentration of the vacancy-based complex defects within the wafer surface is less than 1×10¹² atoms/cm³ at the oxygen partial pressure of 70% or less, and the density of BMD within the wafer surface is 1×10⁵ atoms/cm³ or more.

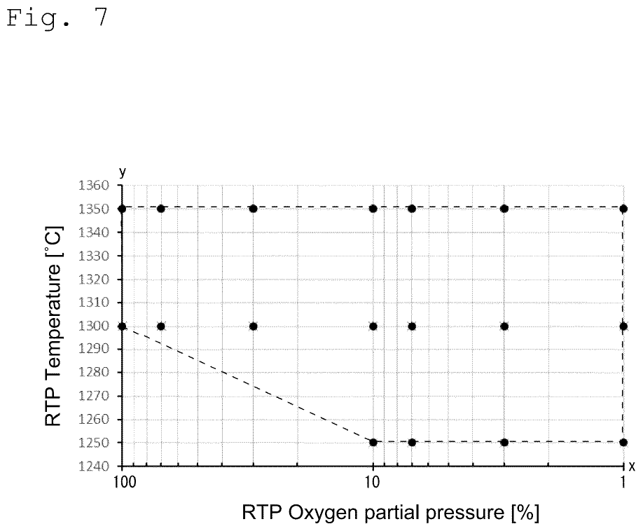

As shown in Table 1 to Table 8, when the oxygen concentration in the silicon wafer is between 1×10¹⁶ atoms/cm³ and less than 1×10¹⁷ atoms/cm³, it is confirmed that in the heat treatment conditions in the region surrounded by the dotted lines as shown in FIG. 6 the concentration of the vacancy-based complex defects within the wafer surface is 1×10¹² atoms/cm³ or more and the density of BMD within the wafer surface is less than 1×10⁵ atoms/cm³.

When the oxygen partial pressure is 10% or more, it is necessary to perform the heat treatment at the oxygen partial pressure and the maximum temperature reached within the region bounded by line segments given by a straight line connecting the two points (x, y)=(10%, 1250° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where, as shown in FIG. 6, the horizontal axis x is the logarithm of the oxygen partial pressure and the vertical axis y is the maximum temperature reached in the rapid thermal processing.

when the oxygen concentration in the silicon wafer is between 1×10¹⁷ atoms/cm³ and less than 7×10¹⁷ atoms/cm³, it is confirmed that in the heat treatment conditions in the region bounded by the dotted lines as shown in FIG. 7 the concentration of the vacancy-based complex defects within the wafer surface is 1×10¹² atoms/cm³ or more and the density of BMD within the wafer surface is less than 1×10⁵ atoms/cm³.

When the oxygen partial pressure is 10% or more, it is necessary to perform the heat treatment at the oxygen partial pressure and the maximum temperature reached within the region bounded by line segments given by a straight line connecting the two points (x, y)=(10%, 1250° C.) and (x, y)=(100%, 1300° C.), a straight line connecting the two points (x, y)=(100%, 1300° C.) and (x, y)=(100%, 1350° C.), and a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where, as shown in FIG. 7, the horizontal axis x is the logarithm of the oxygen partial pressure and the vertical axis y is the maximum temperature reached in the rapid thermal processing.

When the concentration of oxygen in a silicon wafer is more than 7×10¹⁷ atoms/cm³, the concentration of the vacancy-based complex defects and the density of BMD do not meet the requirements of the silicon wafers of the present invention.

### Experiment 2

In Experiment 2, the yield rate (%) of the production of 100 pieces of power devices using the wafers obtained by performing the experiments satisfying the heat treatment conditions within the area surrounded by the dotted lines in FIGS. 6 and 7 and comparative experiments outside the heat treatment conditions described above.

The condition of Experiment 1 is that the maximum temperature reached is 1350° C., the oxygen partial pressure is 3%, and the oxygen concentration in the silicon wafers is 5×10¹⁶ atoms/cm³.

The condition of Experiment 2 is that the maximum temperature reached is 1250° C., the oxygen partial pressure is 10%, and the oxygen concentration in silicon wafers is 5×10¹⁷ atoms/cm³.

The condition of Experiment 3 is that the maximum temperature reached is 1300° C., the oxygen partial pressure is 30%, and the oxygen concentration in silicon wafers is 7×10¹⁷ atoms/cm³.

The condition of Comparative Experiment 1 is that the maximum temperature reached is 1350° C., the oxygen partial pressure is 30%, and the oxygen concentration in silicon wafers is 1×10¹⁸ atoms/cm³.

The condition of Comparative Experiment 2 is that the maximum temperature reached is 1250° C., the oxygen partial pressure is 100%, and the oxygen concentration in silicon wafers is 1×10¹⁸ atoms/cm³.

The graph in FIG. 8 shows the results of Experiments 1 through 3 and Comparative Experiments 1 and 2. The vertical axis of the graph in FIG. 8 is the power device production yield rate (%).

As shown in FIG. 8, each of the yield rates for Experiments 1 to 3 is 90% or more, and the yield rates for Comparative Experiments 1 and 2 largely decrease, confirming the advantageous effects of the present invention on the silicon.

### REFERENCE SIGNS LIST

1 silicon wafer
2 DZ layer
3 bulk region
10 heat treatment apparatus
20 chamber
20a atmosphere gas inlet
20b atmosphere gas outlet
25 reaction space
30 lamp
40 wafer support

What is claimed is:

1. A method of manufacturing a silicon wafer, comprising:
a step of placing wafers, sliced from a silicon single crystal and having an oxygen concentration in the range of 1×10¹⁶ atoms/cm³ to 7×10¹⁷ atoms/cm³, in a chamber and a step of performing a rapid thermal processing at the maximum temperature reached of not less than 1250° C. or not more than 1350° C. in the chamber into which an inert gas having an oxygen partial pressure in the range of 1% to 10% is introduced.

2. The method of manufacturing a silicon wafer, comprising:
a step of placing wafers that are sliced from a silicon single crystal and having an oxygen concentration in the range of 1×10¹⁶ atoms/cm³ to 1×10¹⁷ atoms/cm³ in a chamber;
a step of introducing a mixed gas of oxygen and an inert gas, having an oxygen partial pressure of more than 10% into the chamber; and
a step of performing a heat treatment on silicon wafers at a maximum temperature reached that is within the region bounded by the line segments represented by
a straight line connecting the two points (x, y)=(10%, 1250° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where the horizontal axis x is the logarithm of the oxygen partial pressure and the vertical axis y is the maximum temperature reached during the rapid thermal processing.

3. The method of manufacturing a silicon wafer, comprising:
a step of placing wafers, sliced from a silicon single crystal and having an oxygen concentration in the range of 1×10¹⁷ atoms/cm³ to 7×10¹⁷ atoms/cm³, in a chamber;
a step of introducing a mixed gas of oxygen and an inert gas, having an oxygen partial pressure of more than 10% into the chamber; and
a step of performing a heat treatment on silicon wafers at a maximum temperature reached that is within the region bounded by the line segments represented by a straight line connecting the two points (x, y)=(10%, 1250° C.) and (x, y)=(100%, 1300° C.), a straight line connecting the two points (x, y)=(100%, 1300° C.) and (x, y)=(100%, 1350° C.), a straight line connecting the two points (x, y)=(100%, 1350° C.) and (x, y)=(10%, 1350° C.), and a straight line connecting the two points (x, y)=(10%, 1350° C.) and (x, y)=(10%, 1250° C.), where the horizontal axis x is the logarithm of the oxygen partial pressure and the vertical axis y is the maximum temperature reached in the rapid thermal processing.
